(19) United States
(12) Patent Application Publication
(10) Pub. No.: US 2012/0068728 A1
(43) Pub. Date: Mar. 22, 2012

(54) Probe Card

(76) Inventor: Kenichi Kataoka, Yamanashi (JP)

(21) Appl. No.: 13/375,684

(22) PCT Filed: May 27, 2010
(86) PCT No.: PCT/JP2010/059399

§ 371 Date: Dec. 1, 2011

Related U.S. Application Data
(60) Provisional application No. 61/183,342, filed on Jun. 2, 2009.

(51) Int. Cl. G01R 31/26

(52) U.S. Cl. 324/756.03

(57) ABSTRACT

A probe card to be used with a tester that tests an electrical characteristic of an electronic circuit formed in in a wafer is disclosed. The probe card includes a first transmitter/receiver component that is mounted on a lower surface of a tester board and electrically connected to the tester; a second transmitter/receiver component that is provided to oppose the first transmitter/receiver component and carries out contactless transmission/reception of signals with the first transmitter/receiver component; plural probes that are configured to come in contact with corresponding electrode pads of the electronic circuit and electrically connect the corresponding electrode pads and the second transmitter/receiver component; an expandable chamber having flexibility so that the expandable chamber may be inflated by introducing gas thereinto, thereby moving the plural probes away from the tester board.

### TECHNICAL FIELD

The present invention relates to a probe card for use in testing electronic characteristics of electronic circuits fabricated in an integrated circuit.

### BACKGROUND ART

Electronic circuits such as integrated circuits fabricated on a semiconductor wafer (referred to as a wafer hereinafter) are tested using a probe card. Some probe cards may include plural probes (contactors) to be in contact with corresponding electrode pads of the electronic circuit on the wafer, a flexible print board having the plural probes on a lower surface of the flexible print board, a tester board that supplies test signals output from a tester to the plural probes, and an expandable chamber that is provided between the flexible print board and the tester board and is configured to press the plural probes of the flexible print board onto the corresponding electrode pads of the electronic circuit.

When a compressed gas is introduced into the expandable chamber, the expandable chamber is inflated and thus produces a contact force for the plural probes to be pressed onto the corresponding electrode pads of the wafer subject to testing. The contact force is uniformly applied to the plural probes throughout the wafer and may be controlled by pressure of the compressed gas introduced into the expandable chamber. Therefore, appropriate contacts between the probes and the corresponding electrode pads are easily realized in a large area of the wafer (Patent Documents 1 and 2).

Patent Document 1: U.S. Pat. No. 5,604,446.

Patent Document 2: Japanese Patent Application Laid-Open Publication No. H07-94561.

### SUMMARY OF INVENTION

### Problems to be Solved by the Invention

Because continuously decreasing circuit patterns in recent years lead to decreasing sizes and spaces of electrode pads of an electronic circuit, along with an increasing size of the wafer, the number of the electrodes formed on a wafer is increasing. Therefore, a large number of the probes and corresponding connection wirings need to be formed on the probe card.

Under such connection wirings cannot reach the probes on the lower surface of the flexible print board from a lower inner area of the tester board because the expandable chamber is arranged below the tester board. Therefore, the connection wirings need to extend from a peripheral edge of the tester board to the corresponding probes, and thus a problem of insufficient space for the connection wirings may be caused. In addition, because different connection wirings have different lengths depending on locations of the probes (for example, a connection wiring connecting to a probe located around the center of the wafer is longer than a connection wiring connecting to a probe located near a circumferential edge of the wafer), a problem may be caused in that the test signals output from the tester are out of synchronization, which may impair appropriate testing of the wafer.

The present invention has been made in view of the above, and provides a probe card that enables appropriate testing of electronic circuits on a wafer while maintaining stable contacts between probes and corresponding electrode pads, and a probe apparatus using the probe card.

### Means of Solving the Problems

An aspect of the present invention provides a probe card to be used with a tester that tests an electrical characteristic of an electronic circuit formed in a wafer. The probe card includes a first transmitter/receiver component that is mounted on a lower surface of a tester board and electrically connected to the tester; a second transmitter/receiver component that is provided to oppose the first transmitter/receiver component and carries out contactless transmission/reception of signals with the first transmitter/receiver component; plural probes that are configured to come in contact with corresponding electrode pads of the electronic circuit and electrically connect the corresponding electrode pads and the second transmitter/receiver component; an expandable chamber having flexibility so that the expandable chamber may be inflated by introducing gas thereinto, thereby moving the plural probes away from the tester board.

### BRIEF DESCRIPTION OF THE DRAWINGS

FIG. 1 is a cross-sectional view schematically illustrating a probe apparatus in which a probe card according to a first embodiment of the present invention is used.

FIG. 2A is an explanatory view for explaining an operation of the probe apparatus of FIG. 1.

FIG. 2B is another explanatory view for explaining an operation of the probe apparatus of FIG. 1, in succession to FIG. 2A.

FIG. 2C is another explanatory view for explaining an operation of the probe apparatus of FIG. 1, in succession to FIG. 2B.

FIG. 3 is a schematic view illustrating a probe apparatus in which a probe card according to a second embodiment of the present invention is used.

FIG. 4 is a schematic view illustrating a probe apparatus in which a probe card according to a third embodiment of the present invention is used.

FIG. 5 is a schematic view illustrating a probe apparatus in which a probe card according to a fourth embodiment of the present invention is used.

FIG. 6 is an explanatory view for explaining supplying power to the probe apparatus of FIG. 1.

### MODE(S) FOR CARRYING OUT THE INVENTION

Non-limiting, exemplary embodiments of the present invention will now be described with reference to the accompanying drawings. In the drawings, the same or corresponding reference symbols are given to the same or corresponding members or components.

### First Embodiment

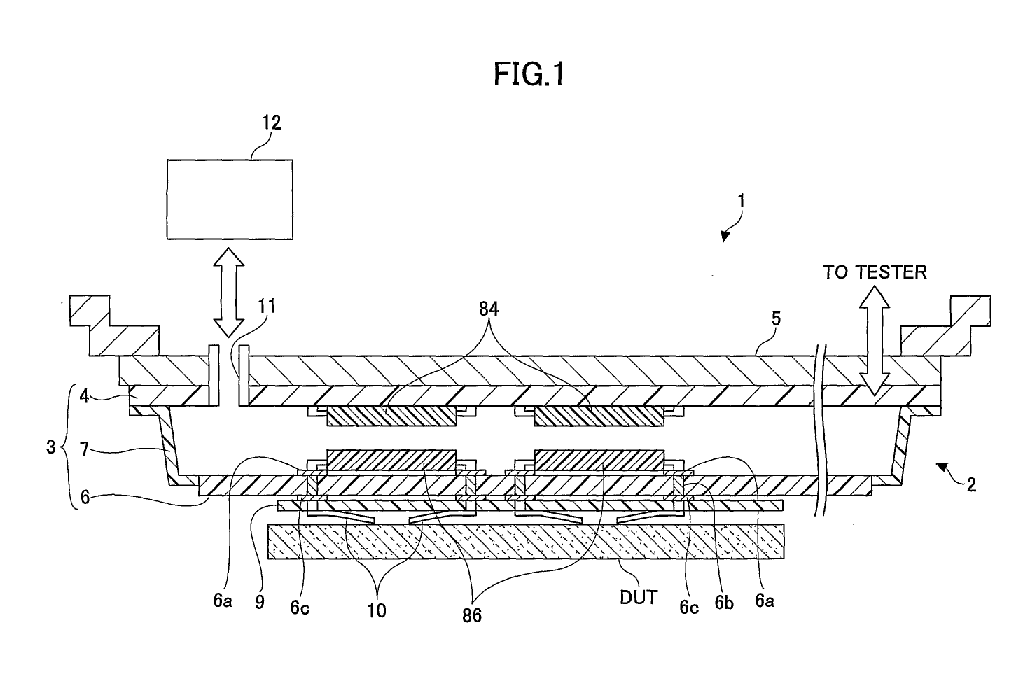

FIG. 1 is a cross-sectional view schematically illustrating a probe apparatus 1 in which a probe card 2 according to a first embodiment of the present invention is used. As shown, the probe card 2 includes an expandable chamber 3 that is expandable by a compressed gas introduced from a pressure control unit 12, transmitter/receiver components 84, 86 arranged inside the expandable chamber 3, a probe board 9 provided on a lower surface of the expandable chamber 3, and plural probes 10 that are provided on a lower surface of the probe board 9 and come in contact with corresponding electrode pads on a wafer subject to testing (referred to a device under test DUT hereinafter).

The expandable chamber 3 includes a tester board 4, a sealing board 6, and a sealing member 7.

The tester board 4 is a printed circuit board having a substantially circular top view shape, and makes electrical connections between a tester (not shown) and the plural probes 10 of the probe board 9. Namely, the tester board 4 intermediates between the tester and the probes in order to send test signals from the tester to the probes 10 and output signals from the device under test DUT to the tester. The tester board 4 is provided on its upper surface with electric circuits and/or components for connecting to the tester and on its lower surface with electrode pads (not shown) for mounting the transmitter/receiver components 84. In addition, the tester board 4 is attached on a lower surface of a supporting plate 5 that provides strength to the tester board 4 when the probes 10 are pressed onto the corresponding electrode pads of the device under test DUT as described later. The supporting plate 5 may be made of metal such as stainless steel and aluminum, and holds the probe card 2.

Incidentally, the tester board 4 and the supporting plate 5 are provided with a gas inlet/outlet 11 that goes through the tester board 4 and the supporting plate 5. The pressure control unit 12 is connected to the gas inlet/outlet 11 via a predetermined pipe (tube). With this, a compressed gas can be introduced at a controlled pressure to the expandable chamber 3, and the compressed gas in the expandable chamber 3 can be evacuated from the expandable chamber 3, through the gas inlet/outlet 11. Although one gas inlet/outlet 11 is illustrated in FIG. 1, two or more gas inlet/outlets 11 may be provided in order to promptly introduce the compressed gas into and evacuate the compressed gas out from the expandable chamber 3.

The sealing board 6 is made of a relatively flexible, electrically insulating material such as plastic and ceramic materials, and has a substantially circular top view shape. The sealing board 6 is provided on its upper surface with pads 6a for mounting the transmitter/receiver components 86 and on its lower surface with pads 6c. In addition, the sealing board 6 has through electrodes 6b that go through the sealing board 6 in order to electrically connect the corresponding pads 6a and pads 6c. The through electrodes 6b may be formed by filling through holes formed in the sealing board 6 with electrically conductive paste and heating the electrically conductive paste, in this embodiment. The through electrodes 6b allow electrical connections between the transmitter/receiver components 86 mounted on the pads 6a on the upper surface of the sealing board 6 and the probe board 9 attached on the lower surface of the sealing board 6. Moreover, the sealing board 6 acts as a lower sealing member of the expandable chamber 3, which seals the expandable chamber 3 in an airtight manner. Incidentally, because the through holes formed in the sealing board 6 are assuredly sealed with the through electrodes 6b, airtightness of the expandable chamber 3 is maintained.

The sealing member 7 has a flattened cylindrical shape, is coupled with a circumferential portion of the tester board 4 and a circumferential edge of the sealing board 6 in an airtight manner, and constitutes the expandable chamber 3 along with the tester board 4 and the sealing board 6. The sealing member 7 is flexible and made of circular bellows and flexible sealing members. When the compressed gas is introduced into the expandable chamber 3 from the pressure control unit 12 through the gas inlet/outlet 11 formed in the tester board 4 and the supporting plate 5, the sealing member 7 is downwardly extended because of its flexibility, and thus the sealing board 6 is downwardly pressed by the sealing member 7, which moves the probe board 9 downward, i.e., away from the tester board 4.

The transmitter/receiver components 84 are arranged on the lower surface of the tester board 4, and the transmitter/receiver components 86 are arranged on the upper surface of the sealing board 6, so that the transmitter/receiver components 84 face the corresponding transmitter/receiver component 86. The transmitter/receiver components 84, 86 facing each other can contactlessly transmit/receive signals or source electrical power. Contactless transmission/reception may be realized by various communication technologies such as a near-field communication, a radio-frequency (RF) communication, and an optical communication. An appropriate communication technology can be selected depending on a distance between the transmitter/receiver components 84, 86 (or a height of the expandable chamber 3), frequencies or pulse intervals of the signals to be contactlessly transmitted/received, the number of signals to be contactlessly transmitted/received, or the like. The transmitter/receiver components 84, 86 are selected based on the communication technologies. For example, when the distance between the transmitter/receiver components 84, 86 facing each other is relatively small and a relatively large number of the transmitter/receiver components 84, 86 are used, the near-field communication is preferable because this communication technology allows communications at an extremely close range, thereby reducing cross talk from adjacent pairs of the transmitter/receiver components 84, 86. Alternatively, when the distance between the transmitter/receiver components 84, 86 facing each other is relatively large, the RF communication technology is preferable. Moreover, when plural signals are simultaneously transmitted/received, a frequency division multiplexing (FDM) technology or a time division multiplexing (TDM) technology may be used. The optical communication is preferable in high speed communication, because the optical communication is relatively immune to interference. Moreover, the optical communication may be used when its cost is relatively affordable.

Incidentally, the transmitter/receiver components 84, 86 may be single transmitter/receiver chips, or may be composed of plural electronic components.

The probe board 9 is made of, for example, silicon or ceramic materials, and supports the plural probes 10 attached on the lower surface of the probe board 9. In addition, electric circuits that electrically connect the through electrodes 6b of the sealing board 6 with the probes 10 are formed on the probe board 9.

The plural probes 10 are attached on the lower surface of the probe board 9, which correspond to electrode pads of the device under test DUT. In this embodiment, the probes 10 have shapes of cantilevers. The probes 10 may be made of, for example, a metal such as nickel and tungsten, or an alloy including nickel and tungsten. The probes 10 may be formed by a micromachining process including photolithography, etching, and electroplating, or a so-called LIGA, which stands for Lithographie, Galvanoform, and Abforming in German, which means lithography, electroplating, and molding, respectively.

The pressure control unit 12 includes a source of a compressed gas, a pressure control valve, a pressure sensor, a valve, a vacuum pump, and the like, which are not shown, in order to control a pressure inside the expandable chamber 3. The source of the compressed gas may be a compressor or a gas cylinder filled with high pressure gas.

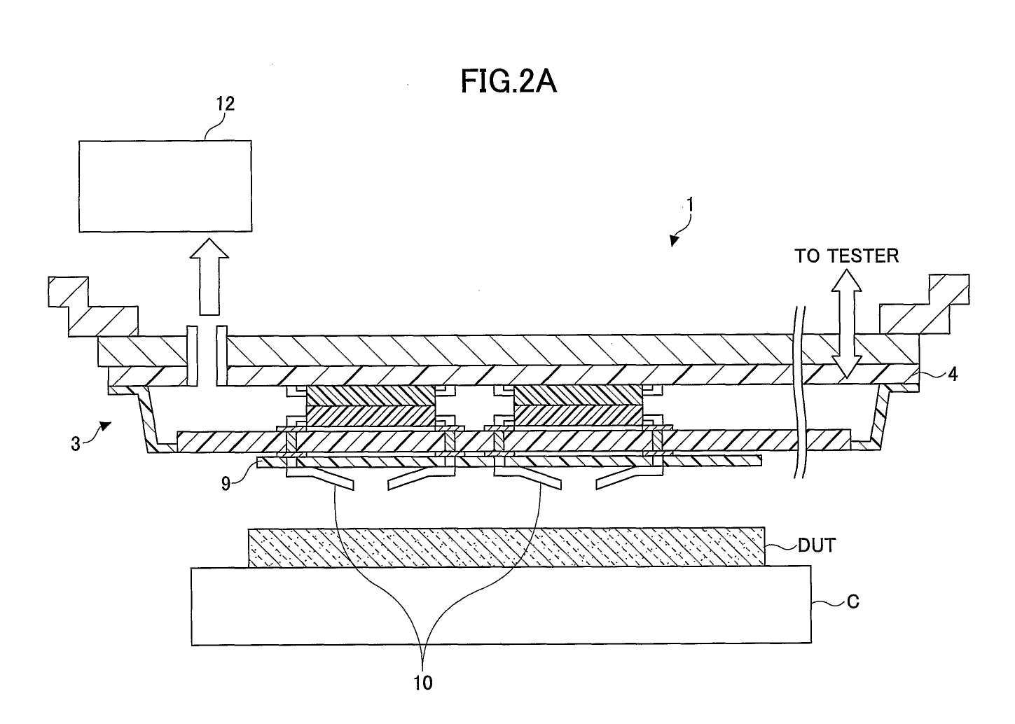

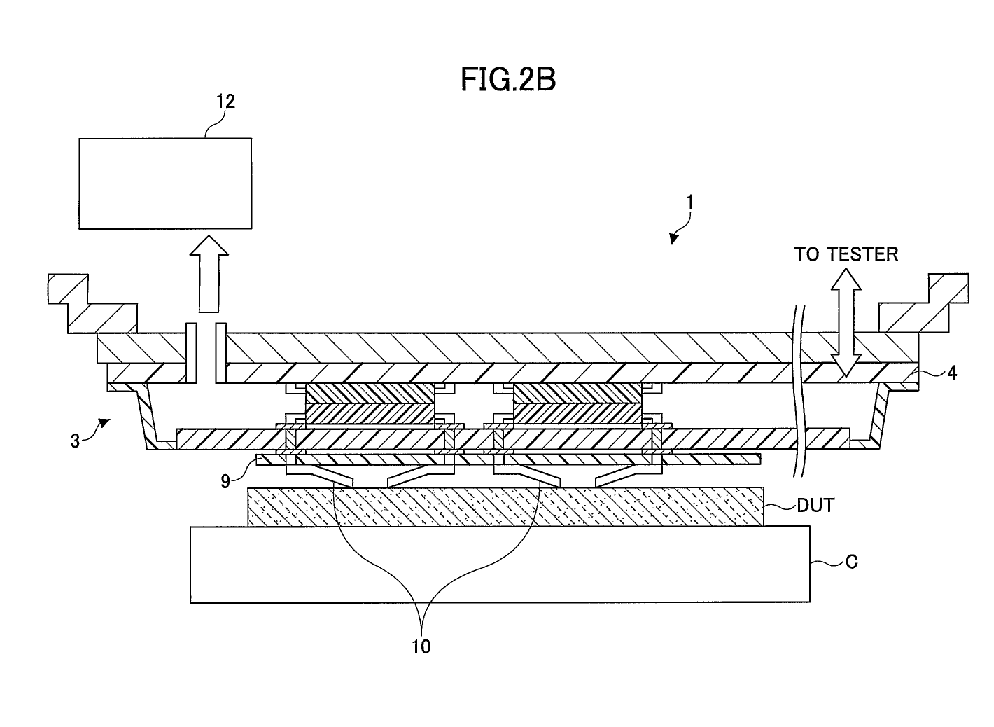

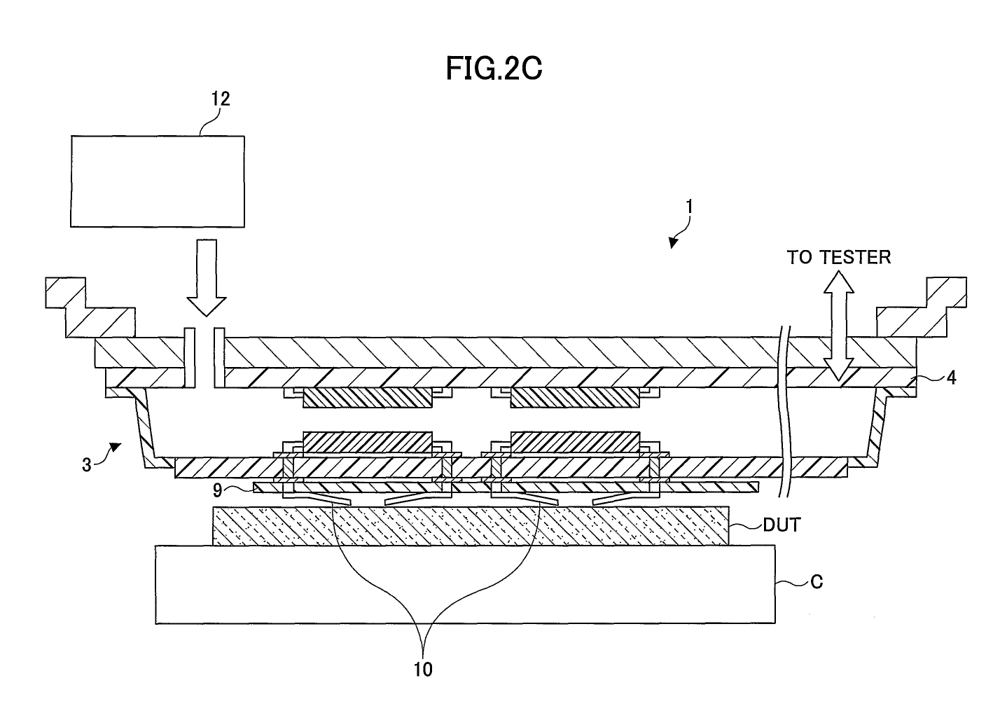

Incidentally, the probe apparatus 1 is provided with a chuck C (see FIGS. 2A through 2C) that supports the device under test DUT below the probe board 9. The chuck C is movable in a horizontal direction in order to align the electrode pads of the device under test DUT with the corresponding probes 10, and in a vertical direction in order to roughly contact the electrode pads with the corresponding probes 10.

Next, operations of the probe apparatus 1 are explained with reference to FIGS. 2A through 2C.

As shown in FIG. 2A, the expandable chamber 3 is maintained at an atmospheric pressure or a slightly reduced pressure by the pressure control unit 12, which makes the expandable chamber 3 deflated. Under this circumstance, the device under test DUT is placed on the chuck C.

Next, as shown in FIG. 2B, the plural electrode pads of the device under test DUT are aligned with the corresponding probes 10 by utilizing alignment marks provided on the device under test DUT and the probe board 9. Then, the aligned device under test DUT is moved upward by the chuck C, and thus the electrode pads are roughly contacted with the corresponding probes 10.

Next, as shown in FIG. 2C, when the compressed gas is introduced into the expandable chamber 3 from the pressure control unit 12, the expandable chamber 3 is inflated and thus presses the probe board 9 downward, i.e., away from the tester board 4, which deforms the probes 10. With counteracting force of the deformed probes 10, the electrode pads of the device under test DUT come in stable contact with the corresponding probes 10. Therefore, the contacts of the electrode pads with the corresponding probes 10 are not broken during testing.

Subsequently, when the test signals are sent to the corresponding transmitter/receiver components 84 attached on the lower surface of the tester board 4 from the tester (not shown), the transmitter/receiver components 84 carry out necessary processes with respect to the input test signals and contactlessly transmit the processed test signals toward the corresponding transmitter/receiver components 86 attached on the upper surface of the sealing board 6. Upon receiving the test signals from the corresponding transmitter/receiver components 84, the transmitter/receiver components 86 carry out necessary processes with respect to the received test signals and output the test signals to corresponding output terminals thereof. Then, the test signals are sent to the corresponding probes 10 through the pads 6a, the through electrodes 6b, the pads 6c, and the electric circuits formed in the probe board 9, and thus input to the corresponding electrode pads on the device under test DUT.

Upon inputting the test signal from the electrode pad, an electronic circuit (not shown) subject to testing formed in the device under test DUT outputs an output signal in accordance with the input test signal. The output signal is input to the transmitter/receiver component 86 through the electric circuit formed in the probe board 9, the pad 6c, the through electrode 6b, and the pad 6a. The transmitter/receiver component 86 carries out necessary processes with respect to the input output signal and contactlessly transmits the output signal toward the transmitter/receiver component 84 that faces the transmitter/receiver component 86. Upon receiving the output signal, the transmitter/receiver component 84 performs necessary processes with respect to the output signal and sends the processed output signal to the tester through the tester board 4. The tester determines whether the electronic circuit subject to testing is normally operating by comparing the test signal and the output signal from the electronic circuit subject to testing formed on the device under test DUT. In such a manner, the device under test DUT is tested.

As stated above, according to the probe card 2 of this embodiment, the test signals from the tester and the output signals output from the electronic circuits subject to testing are contactlessly transmitted/received between the transmitter/receiver components 84, 86 that are provided inside the expandable chamber 3 to face each other. Because the test signals and the output signals are contactlessly transmitted/received by the transmitter/receiver components 84, 86 inside the expandable chamber 3, a need for the wirings electrically connecting the probes and the tester can be eliminated. Therefore, a problem of insufficient space for such wirings in the tester board 4, which may be caused because there is the expandable chamber 3 between the tester board 4 and the probe board 9, and the number of the electrode pads has been increased along with a decreasing circuit size and an increasing wafer size, can be solved.

In addition, because a need for providing the wirings in a narrow space can be eliminated, a production cost can be reduced.

Moreover, there are no large differences in terms of length between electrical paths from the output terminals of the transmitter/receiver component 86 through the probes 10 via the pads 6a, the through electrodes 6b, the pads 6c and the like. Therefore, a problem of out-of-synchronization of signals, which may be caused from the differences in length between the electrical paths, can be solved.

Furthermore, the transmitter/receiver components 84 and/or 86 may have a signal correction function. With such a function, wave-forms of the test signals from the tester and the output signals from the electronic circuits subject to testing formed in the device under test DUT can be corrected by transmitter/receiver components 84 and/or 86 rather than by the tester. Therefore, signal processing loads of the tester can be reduced, thereby improving testing reliability.

In addition, because the probe card 2 according to this embodiment includes the expandable chamber 3, the probes 10 can assuredly come in contact with the corresponding electrode pads of the device under test DUT substantially throughout the device under test DUT by introducing the compressed gas at a controlled pressure into the expandable chamber 3 from the pressure control unit 12 through the gas inlet/outlet 11. Therefore, the device under test DUT can be assuredly tested. Moreover, because the probe board 9 is pressed downward by the expandable chamber 3 inflated by the introduced compressed gas, height differences between the electrode pads of the device under test DUT and/or deflection of the device under test DUT can be compensated for when the probe board 9 is made flexible, thereby assuredly contacting the probes 10 with the electrode pads of the device under test DUT.

Several other embodiments of the present invention are explained in the following. The same operations as explained with reference to FIGS. 2A through 2C in order to allow the plural probes to be in stable contact with the corresponding electrode pads may be carried out even in probe apparatuses in other embodiments. Therefore, repetitive explanations are omitted.

### Second Embodiment

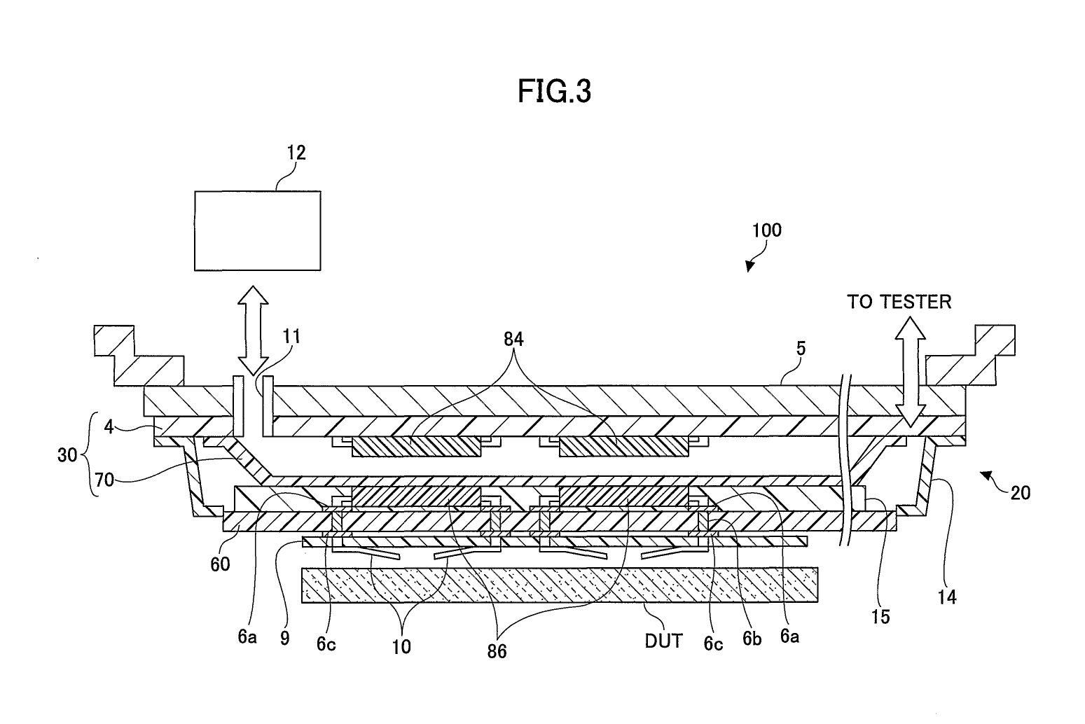

Next, a probe apparatus that uses a probe card according to a second embodiment of the present is explained with reference to FIG. 3. As shown, a sealing member 70 coupled on the lower surface of the tester board 4 in an airtight manner is added to a probe card 20 of a probe apparatus 100 according to the second embodiment. The sealing member 70 and the tester board 4 constitute an expandable chamber 30. Namely, the probe card 20 is composed of the expandable chamber 30, a circuit board 60, the transmitter/receiver components 84, 86, the probe board 9, the plural probes 10, and a supporting component 14.

The sealing member 70 is made of a flexible material in the same manner as the sealing member 7 of the probe card 2 according to the first embodiment, and serves as a lower sealing member of the expandable chamber 30. When the compressed gas is introduced into the expandable chamber 30 through the gas inlet/outlet 11 provided in the supporting plate 5 and the tester board 4, the sealing member 70 is downwardly inflated.

In addition, a spacer 15 having the same height as the transmitter/receiver components 86 is provided between a lower surface of the sealing member 70 and an upper surface of the circuit board 60, and thus the downwardly inflated sealing member presses downward the circuit board 60 via the spacer 15 and the transmitter/receiver components 86. The spacer 15 has openings in which the corresponding transmitter/receiver components 86 are accommodated. In addition, the spacer 15 has a diameter larger than a diameter of the sealing member 70. Therefore, the downward force of the downwardly inflated sealing member 70 is uniformly conveyed to the circuit board 60. Incidentally, plural spacers 15 having the same height as the transmitter/receiver components 86 may be arranged in areas between the transmitter/receiver components 86.

In the same manner as the sealing board 6, the pads 6a are formed on the upper surface of the circuit board 60, and the pads 6c are formed on the lower surface of the circuit board 60. The transmitter/receiver components 86 are mounted using the pads 6a. In addition, the circuit board 60 has the through electrodes 6b that electrically connect the pads 6a with the corresponding pads 6c. The probe board 9 is attached on the lower surface of the circuit board 60. The plural probes 10 provided on the lower surface of the probe board 9 and the transmitter/receiver components 86 are electrically connected via the pads 6a, the through electrodes 6b, the pads 6c, and the like.

The supporting component 14 is coupled with the tester board 4 in order to suspend the circuit board 60 below the expandable chamber 30. Because the supporting component 14 is flexible, when the expandable chamber 30 is downwardly inflated by introducing the compressed gas thereinto, the circuit board 60 can be moved downward. In addition, the supporting component 14 may be configured and coupled with the tester board 4 and the circuit board 60, in the same manner as the sealing member 7 of the first embodiment. However, the supporting component 14 is not necessarily coupled with the tester board 4 and the circuit board 60 in an airtight manner.

In the probe apparatus 100 according to this embodiment, the test signals from the tester and the output signals from the electronic circuits subject to testing are contactlessly transmitted/received between the transmitter/receiver components 84, 86. Therefore, a need for wirings between the tester and the probes 10 is eliminated. Accordingly, the same effects or advantages as those in the first embodiment are obtained.

In addition, in the probe apparatus 100 according to this embodiment, the expandable chamber 30 is composed of the tester board 4 and the sealing member 70, and the transmitter/receiver components 86 are not attached in the sealing member 70. Therefore, the sealing member 70 is provided with no through electrodes that electrically connect the transmitter/receiver components and the probes. Accordingly, the probe apparatus 100 according to this embodiment is more preferable in that airtightness of the expandable chamber 30 is assuredly maintained.

Moreover, because the expandable chamber 30 and the supporting plate 5 can be removed from the supporting component 14, the probe apparatus 100 according to this embodiment is advantageous in that the probe card 20 can be easily re-configured or repaired.

### Third Embodiment

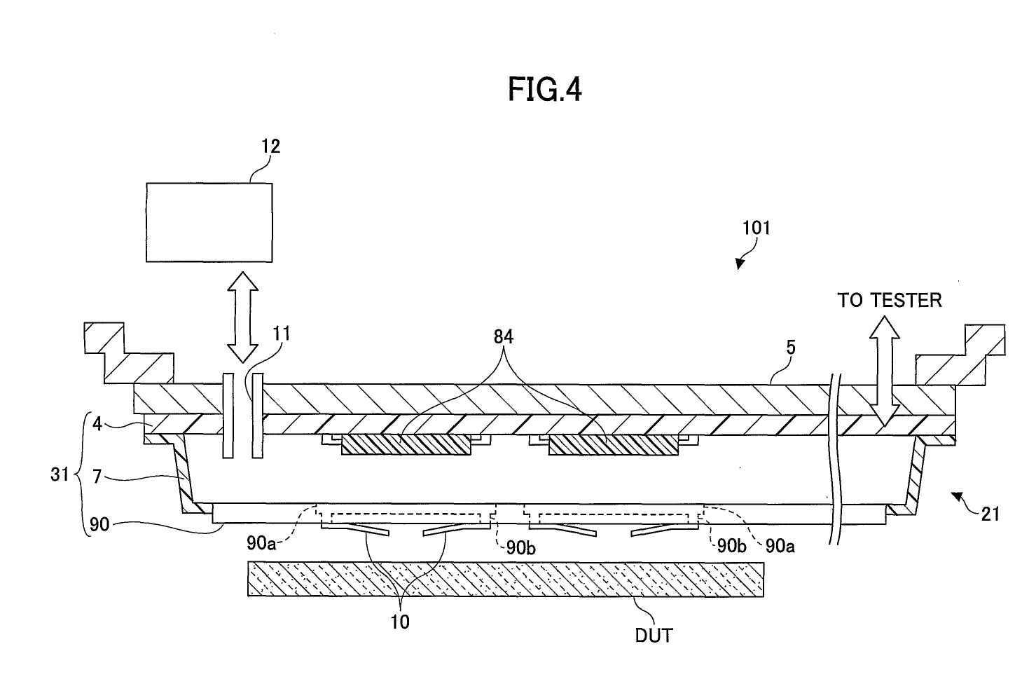

Next, a probe apparatus that uses a probe card according to a third embodiment of the present is explained with reference to FIG. 4. As shown, an expandable chamber 31 is composed of an integrated wafer 90, the sealing member 7, and the tester board 4, which is attached on the lower surface of the supporting plate 5, in a probe apparatus 101 according to the third embodiment of the present invention. In addition, the expandable chamber 31, the transmitter/receiver components 84, the integrated wafer 90, and the plural probes 10 constitute a probe card 21.

Electronic circuits are formed on an upper surface of the integrated wafer 90, and the plural probes 10 are formed on a lower surface of the integrated wafer 90. The electronic circuits are arranged to face the corresponding transmitter/receiver components 84, and include a processing circuit that processes an input signal and a transmitter/receiver circuit 90a that enables contactless transmission/reception with the corresponding transmitter/receiver components 84. In addition, through electrodes 90b that connect the electronic circuits and the corresponding probes 10 are formed in the integrated wafer 90.

With the above configurations, the test signals from the tester are contactlessly transmitted to the transmitter/receiver circuits 90a of the electronic circuits of the integrated wafer 90 from the corresponding transmitter/receiver components 84. Then, the test signals are contactlessly received by the transmitter/receiver circuits 90a of the electronic circuits of the integrated wafer 90, processed by the processing circuits of the electronic circuits, and input to the electrode pads of the device under test DUT via the corresponding probes 10. Upon inputting the test signal through the electrode pads, the electronic circuit subject to testing of the device under test DUT outputs an output signal in accordance with the input test signal to a predetermined electrode pad. The output signal is then input to the electronic circuit of the integrated circuit 90 through the probe 10, and processed by the electronic circuit. Then, the output signal is contactlessly transmitted to the transmitter/receiver component 84 from the transmitter/receiver circuit 90a of the electronic circuit, and then input to the tester via the tester board 4.

As stated above, in the probe apparatus 101 in the third embodiment, the test signals from the tester and the output signals from the electronic circuits subject to testing are contactlessly transmitted/received between the transmitter/receiver components 84 and the transmitter/receiver circuits 90a of the electronic circuit of the integrated wafer 90. Therefore, a need for wirings between the tester and the probes 10 is eliminated. Accordingly, the same effects or advantages as those of the preceding embodiments are obtained.

### Fourth Embodiment

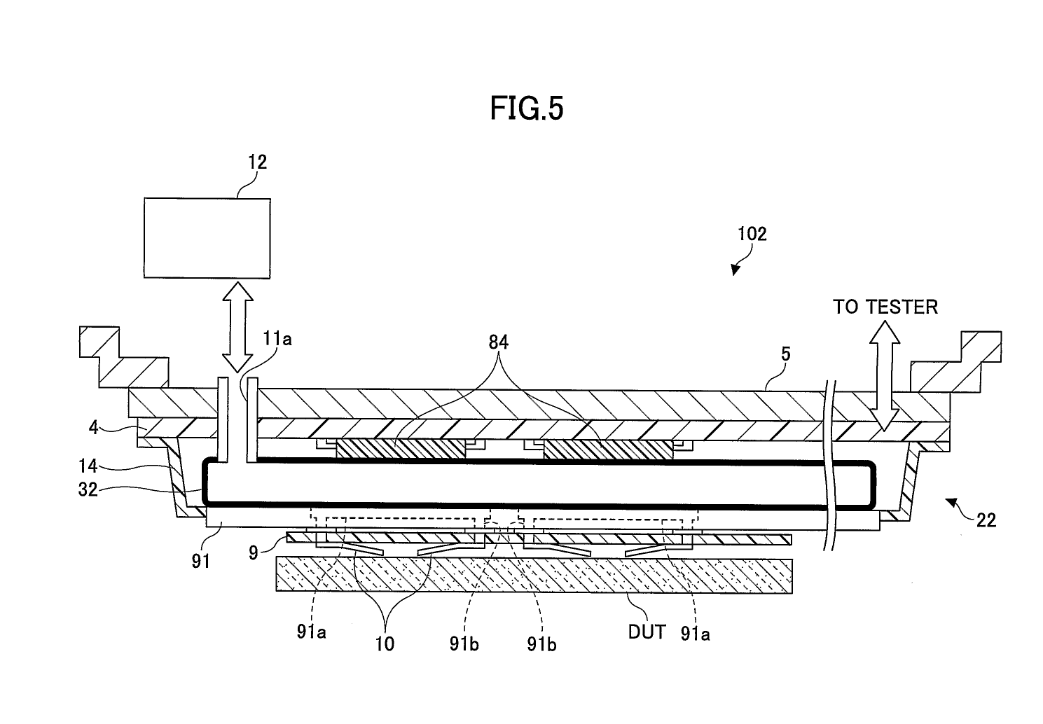

Next, a probe apparatus that uses a probe card according to a fourth embodiment of the present is explained with reference to FIG. 5. As shown, a probe card 22 is composed of an expandable chamber 32, the tester board 4 having the transmitter/receiver components 84 mounted on the lower surface of the tester board 4, an integrated wafer 91 including an electronic circuit where a transmitter/receiver circuit is formed, the probe board 9 attached on a lower surface of the integrated wafer 91, the supporting component 14 that is flexible to suspend the integrated wafer 91 below the expandable chamber 32, and the plural probes 10 provided corresponding to the electrode pads of the device under test DUT on the lower surface of the probe board 9, in a probe apparatus 102 according to the fourth embodiment of the present invention.

The expandable chamber 32 is configured as an independent member in a different manner from the preceding embodiments. The expandable chamber 32 has a shape of a flattened balloon having a substantially circular top view shape, and is accommodated in a space defined by the tester board 4, the supporting component 14, and the integrated wafer 91. The expandable chamber 32 may be made of a flexible material including resins such as polyimide and polyester, rubber, or the like. In addition, the expandable chamber 32 is connected to an inlet/outlet pipe 11a, and is in gaseous communication with an outer atmosphere only through the inlet/outlet pipe 11a. The inlet/outlet pipe 11a is connected to the pressure control unit 12, which connection is not illustrated in FIG. 5, via a pipe.

In the integrated wafer 91, there are formed the electronic circuits including the transmitter/receiver circuits 91a that enable contactless transmission/reception with the corresponding transmitter/receiver components 84 attached on the lower surface of the tester board 4, and the processing circuit that processes an input signal, in the same manner as the integrated wafer 90 of the third embodiment. In addition, through electrodes 91b are formed in the integrated wafer 91 so that the through electrodes 91b are electrically connected to output terminals of the electronic circuits and go through the integrated wafer 91.

Electric circuits that electrically connect the through electrodes 91b of the integrated wafer 91 and the probes 10 are formed in the probe board 9. With this, the test signals are sent to the corresponding probes 10 from the electronic circuits of the integrated wafer 91, and the output signals from the electronic circuits subject to testing of the device under test DUT are sent to the electronic circuits of the integrated wafer 91.

In the probe apparatus 102 in this embodiment, because the transmitter/receiver components 84 carry out contactless transmission/reception of the signals with the corresponding transmitter/receiver circuits 91a included in the electronic circuits of the integrated wafer 91, the same effects or advantages as the preceding embodiments are obtained.

In addition, when the compressed gas is introduced into the expandable chamber 32 from the pressure control unit 12, the expandable chamber 32 is inflated to press the integrated wafer 91 downward. With this, the probes 10 of the probe board 9 attached on the lower surface of the integrated wafer 91 are pressed onto the corresponding electrode pads of the device under test DUT. Therefore, the device under test DUT can be assuredly tested.

Moreover, because the expandable chamber 32 is configured as an independent member, the compressed gas inside the expandable chamber 32 is less likely to be leaked. Furthermore, because such an expandable chamber 32 is accommodated in a space surrounded by the tester board 4, the supporting component 14, and the integrated wafer 91, the supporting component 14, for example, does not need to be coupled to the tester board 4 in an airtight manner. Therefore, the supporting component 14 can be detachably attached to the tester board 4, and thus the integrated wafer 91 supported by the supporting component 14 can be easily replaced depending on the device under test DUT.

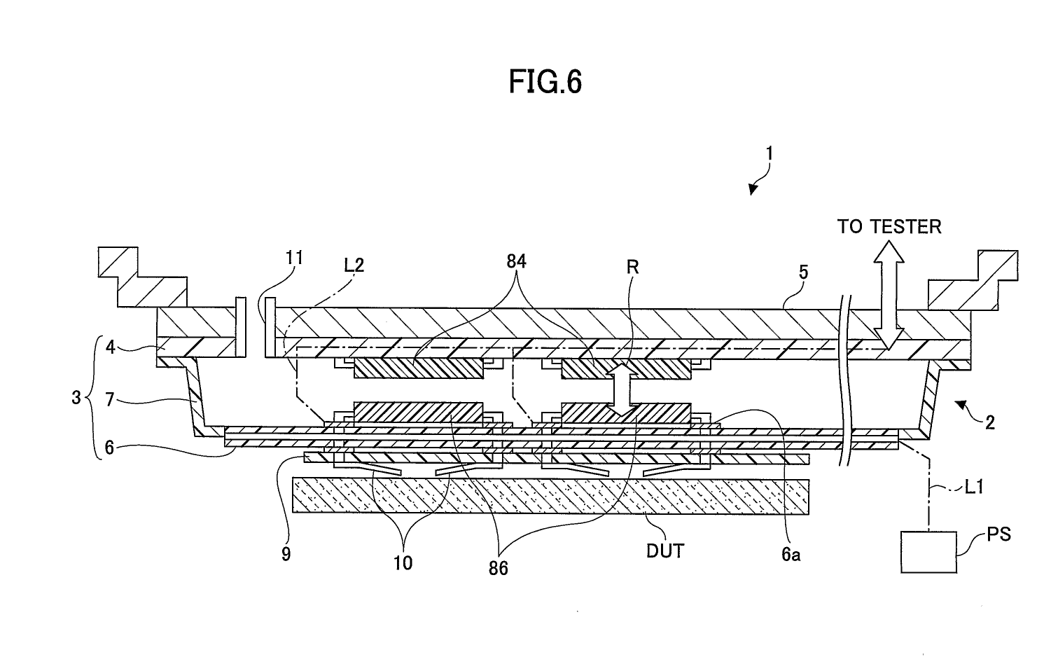

Incidentally, electric power can be supplied to the transmitter/receiver components 86 (or the transmitter/receiver circuits 90a (or 91a) of the electronic circuits in the integrated wafer 90 (or 91)) through the sealing board 6 (or the integrated wafer 90 (or 91)). In this case, it is preferable that the sealing board 6 is configured of a multilayer substrate, an electric circuit for supplying the electric power may be formed in one of plural inner layers of the multilayer substrate, and the one inner layer and an electric power source PS are electrically connected by a wiring L1 (FIG. 6). When the electric power is supplied to the transmitter/receiver components 86 and the like through the sealing board 6, because a large number of wirings are not necessary, a space for the wirings for supplying the electric power is sufficiently retained.

In addition, the electric power may be supplied to the transmitter/receiver components 86 and the like from the tester through the tester board 4. In this case, it is preferable that the tester board 4 is configured of a multilayer substrate, an electric circuit for supplying the electric power is formed in one of the plural inner layers, and the electric circuit and the transmitter/receiver components 86 and the like are electrically connected through wirings L2 (FIG. 6).

Moreover, the electric power is supplied to the transmitter/receiver components 86 and the like by radio transmission R from the transmitter/receiver components 84 and the like (FIG. 6).

While the present invention has been explained with reference to the several embodiments, the present invention is not limited to the above embodiments, but may be variously modified or altered within the scope of the accompanying Claims.

For example, the transmitter/receiver components 86 may be pressed downward by the sealing member 70, without using the spacer 15 in the second embodiment.

In addition, the expandable chamber 32 in the fourth embodiment may have a shape of a flattened closed cylinder configured of an upper surface, a lower surface, and a bellows-like circumferential side wall, rather than a shape of the balloon. Such an expandable chamber 32 can be inflated due to the bellows-like side wall by introducing the compressed gas into the expandable chamber 32 and deflated by evacuating the gas that has been introduced into the expandable chamber 32.

Moreover, the probes 10 may have shapes of pins or springs rather than the cantilevers. In addition, the through electrodes 6b, 90b, 91b may be formed of solder balls, rather than the electrically conductive paste.

Furthermore, the probe board 9 may be separated into plural pieces having, for example, tile-like shapes arranged in a matrix with predetermined gaps between the pieces. In this case, when this probe board 9 is pressed downward by introducing the compressed gas into the expandable chamber 3 or 30, each of the pieces can be pressed downward so that height differences between the electrode pads of the device under test DUT and/or deflection of the device under test DUT can be compensated for because of the flexibility of the sealing board 6 (FIG. 1) or the circuit board 60 (FIG. 3).

This international patent application contains subject matter related to U.S. Provisional Application No. 61/183,342 filed with the United State Patent and Trademark Office on Jun. 2, 2009, the entire contents of which are hereby incorporated herein by reference.

1. A probe card to be used with a tester that tests an electrical characteristic of an electronic circuit formed in a wafer, the probe card comprising:
a first transmitter/receiver component that is mounted on a lower surface of a tester board and electrically connected to the tester;
a second transmitter/receiver component that is provided to oppose the first transmitter/receiver component and carries out contactless transmission/reception of signals with the first transmitter/receiver component;
plural probes that are configured to come in contact with corresponding electrode pads of the electronic circuit and electrically connect the corresponding electrode pads and the second transmitter/receiver component;
an expandable chamber having flexibility so that the expandable chamber may be inflated by introducing gas thereinto, thereby moving the plural probes away from the tester board.

2. The probe card recited in claim 1, further comprising:
a sealing board opposing the tester board below the tester board; and
a first sealing member that is flexible and coupled with the tester board and the sealing board in an airtight manner,
wherein the expandable chamber is configured of the tester board, the sealing board, and the first sealing member, and
wherein the second transmitter/receiver component is arranged on an upper surface of the sealing board.

3. The probe card recited in claim 2, further comprising a probe board that is attached on a lower surface of the sealing board and includes the plural probes on a lower surface of the probe board.

4. The probe card recited in claim 1, further comprising:
a second sealing member that is flexible and coupled with the tester board below the tester board in an airtight manner; and
a circuit board that is suspended from the tester board and opposes the second sealing member,
wherein the expandable chamber is configured of the tester board and the second sealing member, and
wherein the second transmitter/receiver component is arranged on an upper surface of the circuit board.

5. The probe card recited in claim 4, further comprising a probe board that is attached on a lower surface of the circuit board and includes the plural probes on a lower surface of the probe board.

6. The probe card recited in claim 1, further comprising:
a first integrated wafer opposing the tester board below the tester board; and
a third sealing member that is flexible and coupled with the tester board and the first integrated wafer in an airtight manner,
wherein the expandable chamber is configured of the tester board, the first integrated wafer, and the third sealing member, and
wherein a first transmitter/receiver circuit serving as the second transmitter/receiver component is integrated in the first integrated wafer.

7. The probe card recited in claim 6, wherein the plural probes are provided on a lower surface of the first integrated wafer.

8. The probe card recited in claim 1, further comprising:
a second integrated wafer suspended from the tester board below the tester board in order to oppose the tester board; and
an inflatable member that is arranged between the tester board and the second integrated wafer, and serves as the expandable chamber,
wherein a second transmitter/receiver circuit serving as the second transmitter/receiver component is integrated in the second integrated wafer.

9. The probe card recited in claim 8, wherein the plural probes are provided on a lower surface of the second integrated wafer.

10. The probe card recited in claim 1, wherein electric power is supplied to the second transmitter/receiver component through a wiring from the tester board.

11. The probe card recited in claim 1, wherein electric power is wirelessly transmitted from the first transmitter/receiver component to the second transmitter/receiver component.

12. The probe card recited in claim 2, wherein electric power is supplied to the second transmitter/receiver component through the sealing board.

13. The probe card recited in claim 4, wherein electric power is supplied to the second transmitter/receiver component through the circuit board.

14. The probe card recited in claim 6, wherein electric power is supplied to the second transmitter/receiver component through a wiring from the first integrated wafer.

15. The probe card recited in claim 8, wherein electric power is supplied to the second transmitter/receiver component through a wiring from the second integrated wafer.
